(19) United States
(12) Patent Application Publication
(10) Pub. No.: US 2018/0026516 A1
(43) Pub. Date: Jan. 25, 2018

(54) Control Unit for Providing Bias To a Radio Frequency (RF) Switch

(71) Applicant: Limited Liability Company "Siemens", Moscow (RU)

(72) Inventor: Evgeny Valeryevich Ivanov, Moscow (RU)

(21) Appl. No.: 15/542,188

(22) PCT Filed: Jan. 12, 2015
(86) PCT No.: PCT/RU2015/000001

§ 371 Date: Jul. 7, 2017

(51) Int. Cl. H02M 1/08; H03K 17/691; H02M 3/335

(52) U.S. Cl. CPC H02M 1/08; H02M 3/335; H03K 17/691; H02M 2001/0048

(57) ABSTRACT

A control unit for providing a reverse or forward bias to a RF switch module, wherein the control unit includes an internal switch, a reverse bias source to provide the reverse bias signal to the internal switch, a forward bias source to provide the forward bias signal to the internal switch, and a local control module, where the output of the internal switch is configured to be connected to the RF switch module to transmit either the reverse bias signal or the forward bias signal to the RF switch module, where the internal switch controls, via a switching action, transmission of the reverse bias signal and the forward bias signal towards the RF switch module, and where the local control module controls the switching action of the internal switch and controls provision of the reverse bias signal at the first output of the reverse bias source.

### CROSS-REFERENCE TO RELATED APPLICATIONS

This is a U.S. national stage of application No. PCT/RU2015/000001 filed 12 Jan. 2015.

### BACKGROUND OF THE INVENTION

### 1. Field of the Invention

The present invention relates to a bias control circuit for high power RF switch and, more particularly, to a control circuit for providing a forward or reverse bias to a high power RF switch, such as a PIN diode RF switch.

### 2. Description of the Related Art

In variety of RF tracts and applications there is a requirement to regulate RF signals at various places of the tract. One of the ways of regulating RF signals is by using RF switch modules, which may be mechanical switches, electromechanical switches or the ones most recently developed and being used prevalently, switches based on solid state technology such as PIN diodes, or transistors.

For example, when a plurality of RF amplifiers are used to input an RF power combiner, the output power of the RF power combiner is required to be adjusted and optimized to obtain a desired output RF signal. One way to adjust and/or optimize the output RF power is by controlling the RF signals from the RF power amplifiers feeding the RF power combiner. For example, if there is a requirement of lowering power of the RF output of the RF power combiner, then one or more of the RF power amplifiers may be stopped from providing the input to the RF power combiner. Alternatively, for example, if there is a requirement to increase power of the RF output of the RF power combiner, then one or more of the RF power amplifiers may be required to be switched on to provide the input to the RF power combiner. To achieve this control on the RF power amplifiers, i.e., to control the RF power amplifiers such that RF signal from only the desired RF amplifiers is fed into the RF power combiner, each transmission line connecting a given RF amplifier to the RF power combiner is equipped with an RF switch or an RF switch module, usually positioned at each of the RF power inputs of the RF power combiner. Each RF switch module by its switching action allows or disallows a given RF power amplifier from providing its RF signal to the RF power combiner. Usually, each RF switch module is controlled by a separate control unit. The control unit induces the switching action, i.e., turns the RF switch ‘ON’ or ‘OFF’. The control unit is connected to the RF switch module by separate electrical connectors. Information to the control unit to induce the RF switch module may come from an external system, such as a central control system.

In particular, the high power RF applications, such as high power RF amplifier/generator system, may include a plurality of RF power amplifiers each with its separate RF switch module, and each RF switch module having its control unit connected with the RF switch module. Therefore, a lot of switching action may be needed in a given RF application. Furthermore, RF switches based on solid state technology, such as PIN diode based RF switches, can switch RF signal up to several kilowatts. For precise and efficient switching, however, such RF switches need up to 1000 Volts and above as the reverse bias voltage and 1 Ampere and more as the forward bias current. Thus, there is a requirement of having precise switching actions with suitable bias applications to the RF switches and this is lacking in conventional control units.

### SUMMARY OF THE INVENTION

In view of the foregoing, it is an object of the present invention to provide a control unit with a bias control circuit for effective switching action of a RF switch module, particularly for high power RF applications.

This and other objects and advantages are achieved in accordance with the invention by a control unit for providing a reverse or forward bias signal to a RF switch module and a method for providing a reverse or a forward bias signal to the RF switch module from such a control unit, where the control unit includes a reverse bias source, a forward bias source, an internal switch and a local control module. The reverse bias source is configured to provide the reverse bias signal at a first output of the reverse bias source. The forward bias source is configured to provide the forward bias signal at a second output of the forward bias source. The internal switch includes at least a first input, a second input and an output. The first input of the internal switch is configured to receive the reverse bias signal from the first output of the reverse bias source. The second input of the internal switch is configured to receive the forward bias signal from the second output of the forward bias source. The output of the internal switch is configured to be connected to the RF switch module to transmit either the reverse bias signal or the forward bias signal to the RF switch module. The internal switch is configured to control, via a switching action, transmission of the reverse bias signal and the forward bias signal towards the RF switch module. The local control module is electrically connected to the internal switch to control the switching action of the internal switch. The local control module is further electrically connected to the reverse bias source to control providing of the reverse bias signal at the first output of the reverse bias source. Thus, switching the internal switch to provide the forward or the reverse bias to the RF switch module is controlled precisely and accurately.

In an embodiment of the control unit, the local control module is configured to be in communication with an external system and to receive input signal from the external system. The input signal isconfigured to induce the local control module to provide a first control signal to the reverse bias source to control provision of the reverse bias signal at the first output of the reverse bias source and/or the input signal induces the local control module to provide a second control signal to the internal switch to control the switching action of the internal switch. Thus, instructions from an external place or agent may be used to control the internal switch to provide the forward or the reverse bias to the RF switch module.

In another embodiment of the control unit, the local control module is in communication with the reverse bias source to determine whether the reverse bias source is functioning to provide the reverse bias signal at the first output of the reverse bias source. Thus, a feedback of proper functioning or faulty functioning of the reverse bias source is received at the local control module.

In another embodiment of the control unit, the local control module is in communication with the forward bias source to determine whether the forward bias source is functioning to provide the forward bias signal at the second output of the forward bias source. Thus, a feedback of proper functioning or faulty functioning of the forward bias source is received at the local control module.

In another embodiment of the control unit, the local control module is configured to be in communication with the external system. The local control module is further configured to provide a feedback signal to the external system. The feedback signal is representative of the functioning of the reverse bias source in providing the reverse bias signal at the first output of the reverse bias source and/or the functioning of the forward bias source in providing the forward bias signal at the second output of the forward bias source. Thus, feedback of the functioning of the reverse bias source and/or the forward bias source is obtained at the external system for further analysis, further transmission or storage.

In another embodiment of the control unit, the reverse bias source is a DC source. The DC source is configured to provide a negative DC voltage as the reverse bias signal. This provides a simple to implement embodiment of the control unit.

In another embodiment of the control unit, the DC source includes a flyback convertor with a planar transformer having a primary winding, a gap, and a secondary winding, where the secondary winding comprises a rectifier with voltage doubler. This provides a stable and high power source of reverse bias for the RF switch module.

In another embodiment of the present invention, the control unit includes a snubber resistor connected between the first output of the reverse bias source and the first input of the internal switch. Thus, any residual charge or current from the reverse bias source is snubbed when the reverse bias source is not being provided with control signals to provide a reverse bias signal at the first output of the reverse bias source.

In another embodiment of the control unit, the forward bias source includes a stabilized DC source and/or a DC voltage source. This provides a simple arrangement of the control unit.

In another embodiment of the control unit, the internal switch includes a switching element connected between the output and the second input of the internal switch. Thus, transmission of the forward bias from the second input of the internal switch and the output of the internal switch is regulated.

In another embodiment of the control unit, the switching element is a transistor. This makes the control unit compact.

In another embodiment of the control unit, a gate terminal of the switching element is electrically controlled by the local control module such that transmission of the forward bias signal from the second input of the internal switch to the output of the internal switch is controlled by the local control module. Thus, the local control module is able to control the switching element of the internal switch.

In another embodiment of the control unit, the transistor is an insulated-gate bipolar transistor (IGBT). IGBTs are readily available and easy to fabricate and integrate in circuits, thus making the control unit simple, cheap and easy to manufacture.

In another embodiment of the control unit, the transistor is a metal-oxide-semiconductor field-effect transistor (MOSFET). MOSFETs are readily available and easy to fabricate and integrate in circuits, thus making the control unit simple, cheap and easy to manufacture.

It is also an object of the present invention to provide a method for providing a reverse or a forward bias signal to a RF switch module from a control unit. The control unit includes a reverse bias source, a forward bias source, an internal switch and a local control module, all as described hereinabove. The internal switch includes a switching element connected between the second input and the output. In accordance with the method, a first control signal is provided from the local control module to the reverse bias source. Simultaneously, a second control signal is provided from the local control module to the gate terminal of the switching element. Thus, the local control module is empowered to control the reverse bias source as well as the switching element in the internal switch. The switching element in the internal switch, in turn, is in control of the transmission of the forward bias signal from the second input of the internal switch to the output of the internal switch and thus subsequently to the RF switch module. Thus, with the present method, an operator is able to control the forward bias signal as well as the reverse bias signal.

In an embodiment of the method in accordance with the invention, the first control signal induces the reverse bias source to provide the reverse bias signal at the first output of the reverse bias source and the second control signal induces the switching element to block transmission of the forward bias signal from the second input of the internal switch to the output of the internal switch. This provides an embodiment of the method when the reverse bias is desired at the RF switch module.

In another embodiment of the method, the first control signal induces the reverse bias source to cease providing the reverse bias signal at the first output of the reverse bias source and the second control signal induces the switching element to allow transmission of forward bias signal from the second input of the internal switch to the output of the internal switch. This provides an embodiment of the method when the forward bias is desired at the RF switch module.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The present technique is further described hereinafter with reference to illustrated embodiments shown in the accompanying drawings, in which:

FIG. 1 illustrates a control unit layout in accordance with the prior art;

FIG. 2 illustrates a control unit, in accordance with the present invention; and

FIG. 3 is a flowchart of the method in accordance with the invention.

### DETAILED DESCRIPTION OF THE EXEMPLARY EMBODIMENTS

Hereinafter, above-mentioned and other features of the present technique are described in details. Various embodiments are described with reference to the drawing, wherein like reference numerals are used to refer to like elements throughout. In the following description, for purpose of ex-planation, numerous specific details are set forth in order to provide a thorough understanding of one or more embodiments. It may be noted that the illustrated embodiments are intended to explain, and not to limit the invention. It may be evident that such embodiments may be practiced without these specific details.

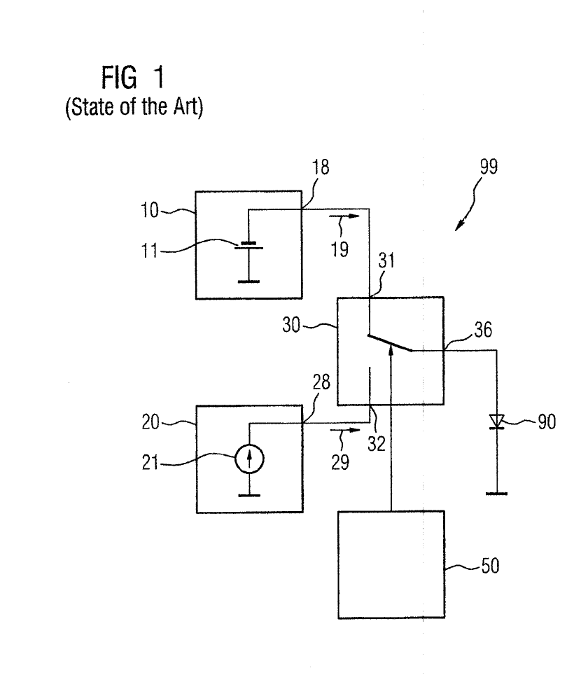

FIG. 1 shows a layout of a control unit 99 for RF application in accordance with the prior art. A RF switch module 90 or simply RF switch 90 is used to control the RF signal. The RF switch 90 is controlled by the control unit 99. The RF switch 90 may be a PIN diode based RF switch or a transistor based RF switch, as are conventionally known in the art of RF applications. The PIN diode based RF switches 90 are especially advantageous because of their precise switching and their very short switching times. Such PIN diode based RF switches 90 can switch an RF signal up to several kilowatts. For precise and efficient switching, however, such RF switches 90, for example, PIN diode based RF switches 90, need up to 1000 Volts and above as a reverse bias voltage and 1 Ampere and more as a forward bias current and this is not provided by the conventional control unit 99 shown in FIG. 1.

The conventional control unit 99 includes a reverse bias source 10, a forward bias source 20, and an internal switch 30. The reverse bias is provided to the RF switch 90 by a reverse bias source 10 that in the conventional control unit 99, is a Negative DC power supply 11 that is connected to one (not shown) of the contacts (not shown) of the RF switch 90. The Negative DC power supply 11 provides a reverse bias signal 19 at a first output 18 of the reverse bias source 10. The reverse bias signal 19 is in the form of a negative DC voltage. The forward bias source 20 that includes a stabilized DC source 21 provides a forward bias signal 29 at a second output 28 of the forward bias source 20. The forward bias signal 29 is in the form of a positive DC current. Furthermore, the internal switch 30 includes at least a first input 31, a second input 32 and an output 36. The reverse bias signal 19 is communicated from the reverse bias source 10 to one of the contacts of the internal switch 30, while the forward bias signal 29 is communicated from the forward bias source 20 to the other contact of the internal switch 30. The control unit 99 feeds the RF switch 30 with a control signal. Depending on the control signal, the internal switch 30 provides a forward or a reverse bias at the output 36. The application of the forward or the reverse bias signals 29, 19 by the control unit 99 to the RF switch 90 transforms the RF switch 90 between its switching states, i.e., the RF switch module 90 is either “closed” when the reverse bias is applied to the RF switch 90 and which is when no RF power is transmitted through the RF switch module 90 or “opened” when the forward bias is applied to the RF switch 90 and when RF power is transmitted through the RF switch module 90.

The power supplies 11, 21 can be based on linear regulators or switching mode power supplies. Linear regulators have low noise, but their efficiency is low too. On the other hand, switching mode power supplies have high efficiency, but require filtering to reduce noise at the outputs 18, 28. Furthermore, the switching action is not well regulated.

The control unit 99 controls the state or position of the RF switch 90 by applying current or voltage to the RF switch 90 and in this way switching it to conductive and non-conductive states accordingly.

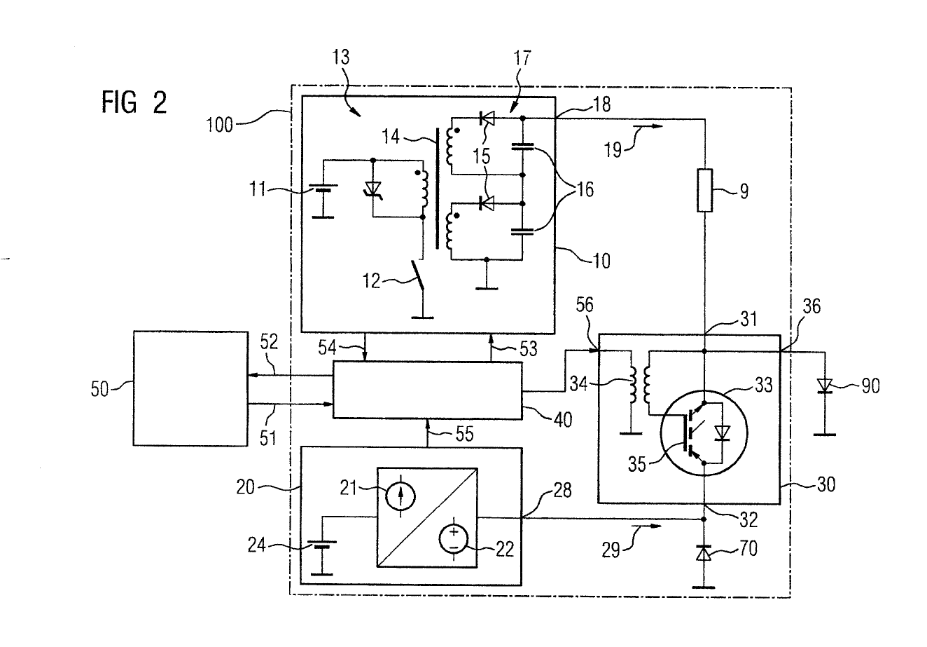

FIG. 2 illustrates a control unit 100 in accordance with the present invention. The control unit 100 is a bias circuit for the RF switch 90 and provides either a reverse bias signal 19 or a forward bias signal 29 to the RF switch module 90. The control unit 100 includes a reverse bias source 10, a forward bias source 20, an internal switch 30 and a local control module 40 (hereinafter LCM, 40). The reverse bias source 10 has an output herein referred to as the first output 18. The reverse bias source 10 provides the reverse bias signal 19 at the first output 18 of the reverse bias source 10.

In one embodiment of the control unit 100, the reverse bias source 10 is a DC source that provides a negative DC voltage as the reverse bias signal 19. The DC source 10 includes a flyback convertor 13 with a planar transformer 14. The planar transformer 14 includes a primary winding, a gap, and a secondary winding. The primary winding receives power from a DC power supply 11. The secondary winding includes a rectifier 13 with voltage doubler 17 and further includes diodes 15 and filter capacitor 16. As a result of the rectifier 13 with the voltage doubler 17 in the secondary winding reverse, voltages on diodes 15 and filter capacitors 16 are reduced. From the reverse bias source 11 of the control unit 100, the reverse bias signal 19 is generated and the reverse bias signal 19 generated in this manner is provided at the first output 18 of the reverse bias source 10.

The forward bias source 20 has an output herein referred to as the second output 28. The forward bias source 20 provides the forward bias signal 29 at the second output 28 of the forward bias source 20.

In one embodiment of the control unit 100, the forward bias source 20 includes a stabilized DC source 21 and/or a DC voltage source 22. Furthermore, an optional microprocessor (not shown) may be present to control the DC current or the DC voltage provided from the forward bias source 20 to the second output 28. A DC power supply 24 is used to provide power for the stabilized DC source 21 and/or the DC voltage source 22.

The control unit 100 further includes the internal switch 30. The internal switch 30 has at least a first input 31, a second input 32 and an output 36. The first input 31 of the internal switch 30 is electrically connected to the first output 18 of the reverse bias source 10. The first input 31 of the internal switch 30 is thus enabled to receive the reverse bias signal 19 from the first output 18 of the reverse bias source 10.

In one embodiment of the control unit 100, a snubber resistor 9 is optionally connected between the first output 18 of the reverse bias source 10 and the first input 31 of the internal switch 30.

The second input 32 of the internal switch 30 is electrically connected to the second output 28 of the forward bias source 20. The second input 32 of the internal switch 30 is thus enabled to receive the forward bias signal 29 from the second output 28 of the forward bias source 20. The output 36 of the internal switch 30 is connected to the RF switch module 90. Through the output 36, either the reverse bias signal 19 or the forward bias signal 29 are transmitted to the RF switching module 90. The internal switch 30 includes at least one switching element 33. The switching element 33 may be, but is not limited to, a transistor, particularly an insulated-gate bipolar transistor (IGBT), particularly a metal-oxide-semiconductor field-effect transistor (MOSFET), and the like. The switching element 33 is connected between the output 36 and the second input 32 of the internal switch 30. By its switching action, the switching element 33 either allows or disallows the transmission of the forward bias signal 29 from the second input 32 of the internal switch 30 to the output 36 of the internal switch 30.

The LCM 40 is electrically connected to the internal switch 30 and the LCM 40 controls the switching action of the internal switch 30, i.e., the switching action of the switching element 33 to be more precise.

In one embodiment, the LCM 40 controls the switching action of the internal switch 30 by sending a second control signal 56 to a switch control 34 positioned inside the internal switch 30. For example, assuming the switching element 33 is a MOSFET, the switch control 34 may be, but is not limited to an electrical conductor winding, which induces a gate voltage or gate current at the gate terminal 35 of the switching element 33, in this case, the MOSFET 33. Thus, the LCM 40 controls or regulates whether the forward bias signal 29 is allowed to pass from the second input 32 through the switching element 33 and to the output 36 of the internal switch 30.

Furthermore, in the control unit 100, the LCM 40 is electrically connected to the reverse bias source 10. The LCM 40 controls the reverse bias source 10 for providing or not providing the reverse bias signal 19 at the first output 18 of the reverse bias source 10. The control of the reverse bias source 10 by the LCM 40 may be achieved in a variety of ways, for example, by sending a first control signal 53 to the LCM 40 via a switch connector 12 which then induces or stops the reverse bias source 10 from generating the reverse bias signal 19 and subsequently either the reverse bias signal 19 is present or absent, respectively, at the first output 18 of the reverse bias source 10.

The LCM 40 may include, but is not limited to, an analog voltage or current signal generator, a processor, or a memory. The LCM 40 is capable of communicating with an external system 50. The external system 50 may be a master control unit 50 from which commands or instructions are sent to the LCM 40 to control the reverse bias source 10 and/or the internal switch 30. The LCM 40 may be connected to the external system 50, for example, via data cable or transmission line and thus is able to receive an input signal 51 from the external system 50. The input signal 51 induces the LCM 40 to provide the first control signal 53 to the reverse bias source 10 and/or to provide the second control signal 56 to the internal switch 30.

The LCM 40 may further be in real time communication with the reverse bias source 10 and may be able to determine whether the reverse bias source 10 is functioning to provide the reverse bias signal 19 at the first output 18 of the reverse bias source 10. This means that when the reverse bias source 10 is generating the reverse bias signal 19, an indication, information or a feedback signal 54 may be provided to the LCM 40 from the reverse bias source 10 to communicate this information to the LCM 40. The feedback signal 54 may not only indicate normal expected functioning of the reverse bias source 10 in generating the reverse bias voltage 19 but may also provide a faulty situation. An example of a faulty situation may be when the reverse bias source 10 is not generating the reverse bias signal 19 although the first control signal 53 carried commands to induce the generation of the reverse bias signal 19.

The LCM 40 may further be in real time communication with the forward bias source 20 and may be able to determine whether the forward bias source 20 is functioning to provide the forward bias signal 29 at the second output 28 of the forward bias source 20. This means that when the forward bias source 20 is generating the forward bias signal 29, an indication, information or a feedback signal 55 may be provided to the LCM 40 from the forward bias source 20 to communicate this information to the LCM 40. The feedback signal 55 may not only indicate normal expected functioning of the forward bias source 20 in generating the forward bias voltage 29 but may also provide a faulty situation. An example of a faulty situation may be when the forward bias source 20 is not generating the forward bias signal 29.

The LCM 40 may be further in communication with the external system 50 to provide a feedback signal 52 to the external system 50. The feedback signal 52 is representative of the feedback signal 54 and/or the feedback signal 55.

For the control unit 100, when it is desired or required to have the reverse bias signal 19 at the output 36 of the internal switch 30, the LCM 40 sends the first control signal 53 to the reverse bias source 10 to induce the reverse bias source 10 to generate the reverse bias signal 19, and at the same time the LCM 40 sends the second control signal 56 to the internal switch 30 and thereby closes the internal switch 30, i.e., not allow the transmission of forward bias signal 29 from the second input 32 to the output 36 of the internal switch 30. Thus, the reverse bias signal 19 exits the output 36 of the internal switch 30 and provides a reverse bias to the RF switch module 90, i.e., PIN diode 90. Alternatively, when it is desired or required to have the forward bias signal 29 at the output 36 of the internal switch 30, the LCM 40 sends the first control signal 53 to the reverse bias source 10 to induce the reverse bias source 20 to not generate the reverse bias signal 19, and at the same time the LCM 40 sends the second control signal 56 to the internal switch 30 and thereby opens the internal switch 30, i.e., allows the transmission of forward bias signal 29 from the second input 32 to the output 36 of the internal switch 30. The filter capacitors 16 may be discharged through the snubber resistor 9. Thus, the forward bias signal 29 exits the output 36 of the internal switch 30 and provides a forward bias to the RF switch module 90, i.e., PIN diode 90.

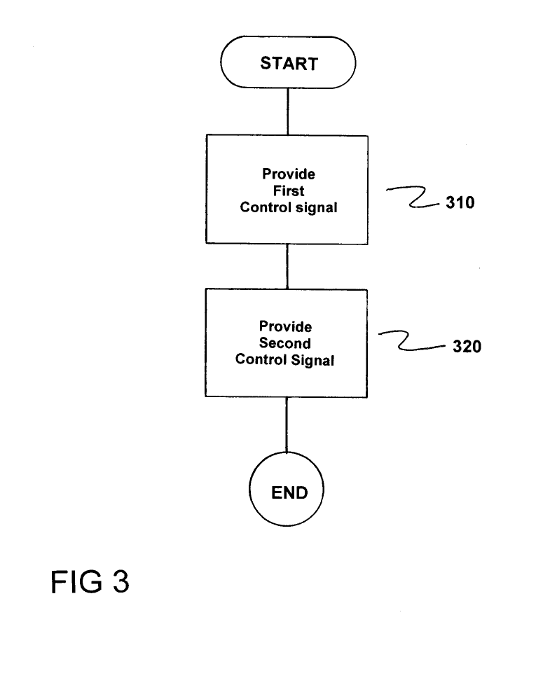

FIG. 3 is a flowchart of a method for providing a reverse 19 or a forward bias signal 29 from a control unit 100 to a radio frequency (RF) switch module 90, where the control unit 100 comprises a reverse bias source 10 configured to provide the reverse bias signal 19 at a first output 18 of the reverse bias source 10, a forward bias source 20 configured to provide the forward bias signal 29 at a second output 28 of the forward bias source 20, an internal switch 30 having at least a first input 31, a second input 32, an output 36 and a switching element 33 connected between the second input 32 and the output 36. Here, the first input 31 of the internal switch 30 is configured to receive the reverse bias signal 19 from the first output 18 of the reverse bias source 10, the second input 32 of the internal switch 30 is configured to receive the forward bias signal 29 from the second output 28 of the forward bias source 20 and the output 36 of the internal switch 30 is configured to be connected to the RF switch module 90 to transmit one of (i) the reverse bias signal 19 and (ii) the forward bias signal 29 to the RF switch module 90, and the internal switch 30 being configured to control, via a switching action, transmission of the reverse bias signal 19 and the forward bias signal 29 towards the RF switch module 90. The control unit 100 additionally includes a local control module 40 electrically connected to the internal switch 30 and configured to control the switching action of the internal switch 30 and electrically connected to the reverse bias source 10 and configured to induce the reverse bias source 10 to provide the reverse bias signal 19 at the first output 18 of the reverse bias source 10, where a gate terminal 35 of the switching element 33 is electrically controlled by the local control module 40 such that transmission of the forward bias signal 29 from the second input 32 to the output 36 of the internal switch 30 is controlled by the local control module 40.

With reference to FIG. 3, the method comprises providing a first control signal 53 from the local control module 40 to the reverse bias source 10, as indicated in step 310. Next, a second control signal 56 is provided from the local control module 40 to the gate terminal 35 of the switching element 33, as indicated in step 320.

Thus, while there have been shown, described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1.-17. (canceled)

18. A control unit for providing a reverse or a forward bias signal to a radio frequency (RF) switch module, the control unit comprising:
a reverse bias source configured to provide the reverse bias signal at a first output of the reverse bias source;
a forward bias source configured to provide the forward bias signal at a second output of the forward bias source;
an internal switch having at least a first input, a second input and an output, the first input of the internal switch being configured to receive the reverse bias signal from the first output of the reverse bias source, the second input of the internal switch being configured to receive the forward bias signal from the second output of the forward bias source, the output of the internal switch being configured to be connected to the RF switch module to transmit one of (i) the reverse bias signal and (ii) the forward bias signal to the RF switch module, and the internal switch being configured to control, via a switching action, transmission of the reverse bias signal and the forward bias signal towards the RF switch module; and
a local control module electrically connected to the internal switch to control the switching action of the internal switch and electrically connected to the reverse bias source to control provision of the reverse bias signal at the first output of the reverse bias source.

19. The control unit according to claim 18, wherein the local control module is configured to be in communication with an external system and to receive an input signal from the external system; and
wherein at least one of (i) the input signal is configured to induce the local control module to provide a first control signal to the reverse bias source to control provision of the reverse bias signal at the first output of the reverse bias source and (ii) the input signal induces the local control module to provide a second control signal to the internal switch to control the switching action of the internal switch.

20. The control unit according to claim 18, wherein the local control module is in communication with the reverse bias source to determine whether the reverse bias source is functioning to provide the reverse bias signal at the first output of the reverse bias source.

21. The control unit according to claim 19, wherein the local control module is in communication with the reverse bias source to determine whether the reverse bias source is functioning to provide the reverse bias signal at the first output of the reverse bias source.

22. The control unit according to claim 20, wherein the local control module is in communication with the forward bias source to determine whether the forward bias source is functioning to provide the forward bias signal at the second output of the forward bias source.

23. The control unit according to claim 22, wherein the local control module is configured to be in communication with the external system and configured to provide a feedback signal to the external system; and
wherein the feedback signal represents at least one of (i) whether the reverse bias source is functioning to provide the reverse bias signal at the first output of the reverse bias source and (ii) whether the forward bias source is functioning to provide the forward bias signal at the second output of the forward bias source.

24. The control unit according to claim 18, wherein the reverse bias source comprises a DC source; and wherein the DC source is configured to provide a negative DC voltage as the reverse bias signal.

25. The control unit according to claim 18, wherein the DC source comprises a flyback convertor with a planar transformer having a primary winding, a gap, and a secondary winding comprising a rectifier with a voltage doubler.

26. The control unit according to claim 18, further comprising: a snubber resistor connected between the first output of the reverse bias source and the first input of the internal switch.

27. The control unit according to claim 18, wherein the forward bias source comprises at least one of (i) a stabilized DC source and (ii) a DC voltage source.

28. The control unit according to claim 18, wherein the internal switch comprises a switching element connected between the output and the second input of the internal switch.

29. The control unit according to claim 28, wherein the switching element is a transistor.

30. The control unit according to claim 29, wherein a gate terminal of the switching element is electrically controlled by the local control module such that transmission of the forward bias signal from the second input of the internal switch to the output of the internal switch is controlled by the local control module.

31. The control unit according to claim 29, wherein the transistor is an insulated-gate bipolar transistor.

32. The control unit according to claim 30, wherein the transistor is an insulated-gate bipolar transistor.

33. The control unit according to claim 29, wherein the transistor is a metal-oxide-semiconductor field-effect transistor.

34. The control unit according to claim 30, wherein the transistor is a metal-oxide-semiconductor field-effect transistor.

35. A method for providing a reverse or a forward bias signal from a control unit to a radio frequency (RF) switch module, the control unit comprising a reverse bias source configured to provide the reverse bias signal at a first output of the reverse bias source, a forward bias source configured to provide the forward bias signal at a second output of the forward bias source, an internal switch having at least a first input, a second input, an output and a switching element connected between the second input and the output, the first input of the internal switch being configured to receive the reverse bias signal from the first output of the reverse bias source, the second input of the internal switch being configured to receive the forward bias signal from the second output of the forward bias source and the output of the internal switch being configured to be connected to the RF switch module to transmit one of (i) the reverse bias signal and (ii) the forward bias signal to the RF switch module, and the internal switch being configured to control, via a switching action, transmission of the reverse bias signal and the forward bias signal towards the RF switch module, and a local control module electrically connected to the internal switch and configured to control the switching action of the internal switch and electrically connected to the reverse bias source and configured to induce the reverse bias source to provide the reverse bias signal at the first output of the reverse bias source, and a gate terminal of the switching element being electrically controlled by the local control module such that transmission of the forward bias signal from the second input to the output of the internal switch is controlled by the local control module, the method comprising:
providing a first control signal from the local control module to the reverse bias source; and
providing a second control signal from the local control module to the gate terminal of the switching element.

36. The method according to claim 35, wherein the first control signal from the local control module to the reverse bias source induces the reverse bias source to provide the reverse bias signal at the first output of the reverse bias source and the second control signal from the local control module to the gate terminal induces the switching element to block transmission of the forward bias signal from the second input of the internal switch to the output of the internal switch.

37. The method according to claim 35, wherein the first control signal from the local control module to the reverse bias source induces the reverse bias source to cease providing the reverse bias signal at the first output of the reverse bias source and the second control signal from the local control module to the gate terminal induces the switching element to allow transmission of forward bias signal from the second input of the internal switch to the output of the internal switch.
